(19) United States
(12) Patent Application Publication
(10) Pub. No.: US 2015/0043747 A1
(43) Pub. Date: Feb. 12, 2015

(54) Microphone System and Method

(71) Applicant: The Secretary of State for Business, Innovation & Skills of Her Majesty's Britannic Government, London (GB)

(72) Inventor: Richard Barham, London (GB)

(21) Appl. No.: 14/384,724

(22) PCT Filed: Mar. 12, 2013
(86) PCT No.: PCT/GB2013/050608

§ 371 Date: Sep. 12, 2014

(30) Foreign Application Priority Data
Mar. 12, 2012 (GB) 1204305.5

(51) Int. Cl. H03G 3/20

(52) U.S. Cl. CPC H03G 3/20
USPC 381/98

(57) ABSTRACT

A microphone system (10) includes a microphone sub-system including a microphone (14); and an acoustic filter (12). The acoustic filter (12) can include a resistive element (20) and a closed volume configured to act as an acoustic compliance. The acoustic filter (12) is configured to have a frequency response substantially equal and opposite to a difference between a frequency response of the microphone sub-system and a desired frequency response of the system (10).

The present invention relates to a microphone system and method, for example to a method and apparatus for compensating for an undesired frequency response of a microphone system.

Sound level meters are used widely for acoustic measurement and in particular for the measurement of noise. The sound level meter is predominantly an electronic instrument, but uses a measurement microphone as the electroacoustic transducer. In order for measurements made with a sound level meter to be reliable and reproducible, specification standards have been prepared by the International Electrotechnical Commission (IEC) detailing their acoustic, mechanical and electrical performance. The IEC 61672 series actually specifies two performance classes, Class 1 and Class 2, with Class 1 denoting the higher performance. References to IEC 61672 herein are in particular references to IEC 61672 2001. Particular noise measurement applications (for example for compliance with the Noise Act, or EU Directives) may then call for instrumentation of a given class to be used. IEC 61672 notwithstanding, there are many instruments that do not conform to any national or international specification standards, and their performance is indeterminate. Of all the components of a sound level meter, the performance of the microphone is often the determining factor in the overall specification that can be achieved.

The key feature distinguishing a measurement microphone from one used to pick up sound for replay, broadcast or recording, is that the sensitivity must be known precisely. The microphone sensitivity, expressed in terms of the output voltage for a given sound pressure, enables the level of the detected sound to be quantified. The microphone sensitivity is determined through calibration, and is additionally required to be stable, and not to change significantly with frequency.

Ideally, measurement microphones should also be so small as to not perturb the sound field being measured. However, practical measurement microphone designs cannot be made sufficiently small. This leads to the microphone having a frequency response that depends on the type of sound field being measured. When a propagating sound wave is incident upon a microphone located in the field for the purpose of making a measurement, the presence of the microphone causes the sound wave to be diffracted. The degree of diffraction depends on the relative magnitude of the acoustic wavelength and the characteristic dimensions of the microphone (usually the diameter), as well as the direction of incidence. Hardly any diffraction occurs at low frequencies, but as the frequency increases, diffraction causes the incident sound to be focussed towards the centre of the microphone, where it is most sensitive, resulting in an apparent increase in sensitivity, of around 9 dB to 10 dB for the normal incidence direction.

However, this diffraction phenomenon only occurs when the microphone is exposed to a propagating sound field. If the sound is generated in a small cavity such that the resulting sound pressure field is uniformly distributed, then a microphone exposed to this field will not induce diffraction, and the sound pressure will exert uniformly over the microphone diaphragm.

This dependence of the microphone frequency response on the type of sound field to be measured causes microphone designers to create different devices optimised for a particular idealised sound field type. It is therefore common to find pressure microphones designed to have a constant sensitivity as a function of frequency (frequency response) when exposed to a pressure field; free-field microphones having a flat frequency response for a normally incident propagating plane wave; and diffuse-field microphones with a flat frequency response in a diffuse sound field where the direction of sound incidence is randomly distributed.

For measurement microphones of electrostatic construction (so-called condenser microphones), the different responses are obtained by adjusting the mechanical damping mechanism within the microphone construction. This is achieved with a perforated backplate located close to the microphone diaphragm. The perforations facilitate airflow in and out of the space between the diaphragm and backplate, so the degree of damping can be controlled by the size and number of holes in the backplate. Pressure microphones have the least amount of damping and free-field microphones the most (fewer and or smaller holes by comparison). However the specification of the damping mechanism is part of the design process of the microphone and cannot be altered (for example by the user) after the microphone has been constructed. In particular, the size/number of backplate holes is determined during the design of a microphone model, and then fixed during production. It is not changed for individual devices and most importantly, cannot be adjusted (e.g. by the user) post-production.

In addition, sound is a pervasive phenomenon, and a thorough noise assessment ideally requires a distributed measurement of the sound field over the entire area of interest. The majority of acoustical measurements in air are made using working standard microphones in conjunction with sound level meters or sound analysers. As mentioned above, such equipment is costly and requires specialist knowledge for its operation. So in many practical noise measurement applications the economic constraints limit the degree of spatial sampling, and indeed temporal sampling, that can realistically be achieved. Consequently, noise assessments are often carried out at a single selected location, or at best at a limited number of locations, and permanent installations are often only considered in the most critical applications (for example airport noise monitoring).

The cost of the measurement microphone represents a significant proportion of the overall cost of a sound level meter. In addition, manufacturers tend to load sound level meters with a wide range of functions and measurands for a wide variety of measurement types. Often only a small selection of these is needed for a particular application. However the comprehensive functionality adds considerably to the overall cost and complexity of the system.

Furthermore, a significant proportion of noise measurements need to be made outdoors. Since the microphone and, to a lesser extent, the associated electronics of a sound level meter are sensitive to meteorological conditions (especially wind and rain), it is common for a range of accessories to be made available to offer the necessary level of protection. However, these ‘weather-proofing’ kits both add to the cost of the equipment, and change the performance of the instrumentation. Consequently, performance approvals and verifications require the accessories that will be used to be specified, and their influence included in the testing. The user is then obligated to use these accessories to be assured that the equipment performance is maintained.

The present invention seeks to provide an improved microphone system and method.

According to an aspect of the invention there is provided a method of compensating for an undesired frequency response of a microphone system, wherein the microphone system includes a microphone, the method including determining a desired frequency response of the system; determining an actual frequency response of the system; determining a compensatory response being substantially equal and opposite to the difference between the actual frequency response of the system and the desired frequency response of the system; and providing an acoustic filter having a response substantially equal to the compensatory response.

According to an aspect of the invention, there is provided a microphone system, including: a microphone sub-system including a microphone; and an acoustic filter; wherein the acoustic filter has a frequency response substantially equal and opposite to a difference between a frequency response of the microphone sub-system and a desired frequency response of the system.

Preferably, the microphone system is a measurement microphone system, and the microphone system preferably enables a complete sound level meter with which it is used to conform to IEC 61672 2001.

According to an aspect of the invention, there is provided a method of compensating for an undesired frequency response of a microphone sub-system for a microphone system, wherein the microphone sub-system includes a microphone, the method including:

determining a desired frequency response of the sub-system;
determining an actual frequency response of the sub-system;
determining a compensatory response being substantially equal and opposite to the difference between the actual frequency response of the sub-system and the desired frequency response of the sub-system; and
providing an acoustic filter including a resistive element, and a closed volume configured to act as an acoustic compliance, the acoustic filter being configured to have a frequency response substantially equal to the compensatory response.

According to an aspect of the invention, there is provided a method of compensating for an undesired frequency response of a microphone sub-system for a microphone system, wherein the microphone sub-system includes a microphone, the method including:

determining an actual frequency response of the sub-system;
determining a compensatory response being substantially equal and opposite to the difference between the actual frequency response of the sub-system and a desired frequency response of the sub-system, wherein the desired frequency response of the sub-system is a linear frequency response for the frequency range 10 Hz to 20 kHz; and
providing an acoustic filter having a response substantially equal to the compensatory response.

According to an aspect of the invention, there is provided a microphone system, including:
a microphone sub-system including a microphone; and
an acoustic filter;
wherein the acoustic filter includes a resistive element, and a closed volume configured to act as an acoustic compliance, the acoustic filter being configured to have a frequency response substantially equal and opposite to a difference between a frequency response of the microphone sub-system and a desired frequency response of the system.

According to an aspect of the invention, there is provided a microphone system, including:
a microphone sub-system including a microphone; and
an acoustic filter;
wherein the acoustic filter has a frequency response substantially equal and opposite to a difference between a frequency response of the microphone sub-system and a desired frequency response of the system, the desired frequency response of the system being a linear frequency response for the frequency range 10 Hz to 20 kHz.

According to an aspect of the invention, there is provided a method of designing a filter for compensating for an undesired frequency response of a microphone sub-system for a microphone system, wherein the microphone sub-system includes a microphone, the method including:

determining a desired frequency response of the sub-system;
determining an actual frequency response of the sub-system;
determining a compensatory response being substantially equal and opposite to the difference between the actual frequency response of the sub-system and the desired frequency response of the sub-system; and
determining a configuration of an acoustic filter to provide a frequency response substantially equal to the compensatory response. The filter is preferably configured so that a microphone system, including the microphone sub-system and the filter has a frequency response substantially corresponding to the desired frequency response of the sub-system.

According to an aspect of the invention, there is provided a method of designing a filter for compensating for an undesired frequency response of a microphone sub-system for a microphone system, wherein the microphone sub-system includes a microphone, the method including:

determining a desired frequency response of the sub-system;
determining an actual frequency response of the sub-system;
determining a compensatory response being substantially equal and opposite to the difference between the actual frequency response of the sub-system and the desired frequency response of the sub-system; and
determining a configuration of a closed volume to act as an acoustic compliance, and a configuration of a resistive element, wherein the determined configurations of a resistive element and acoustic compliance are usable in an acoustic filter to provide a frequency response substantially equal to the compensatory response.

Preferred embodiments are therefore able to adapt a microphone to provide a desired frequency response, for example to be optimised for a particular idealised sound field type, without needing to adjust the internal configuration of the microphone itself. In other words, preferred embodiments are able to compensate for an undesired frequency response of a microphone system by an external acoustic filter. The filter could be considered as a diffraction corrector.

The term frequency response is used herein to refer to sensitivity to sound as a function of the frequency of sound. For example, the frequency response of a system can be an output voltage of the system as a function of the frequency of sound pressure incident on the system. In addition, the frequency response of any particular component is used herein to refer to the influence on the overall frequency response of the system contributed by that component.

The actual frequency response of the sub-system refers to the frequency response of the sub-system without modification by the filter.

In some embodiments, the desired frequency response of the system corresponds to a free-field microphone. The actual frequency response of the microphone sub-system may correspond to a pressure microphone.

In some embodiments, the desired frequency response of the system provides a rise and then a fall or a fall and then a rise around a predetermined frequency to accentuate or attenuate a feature of sound.

Preferred embodiments provide advantages over a microphone in which damping is provided by a perforated backplate since preferred embodiments allow a frequency response of a microphone system to be tailored to the specific requirements of the individual system and are not limited by the predetermined damping applied to the microphone during production.

In addition, the use of an external filter enables a wider range of microphones to be used, and is therefore able to reduce the cost of the microphone system.

Preferably, providing an acoustic filter includes enclosing a microphone within the acoustic filter, or the filter is configured to enclose the microphone. This is able to provide a compact element, which is beneficially shielded from meteorological conditions, such as wind and rain.

In a preferred embodiment, the microphone is an MEMS microphone.

According to an aspect of the invention, there is provided a measurement microphone system including an MEMS microphone preferably configured to enable a complete sound level meter with which it is used to conform to IEC 61672. In one embodiment, the MEMS microphone is exposed i.e. the MEMS microphone is not provided in a resonant cavity.

Micro-electro-mechanical-systems (MEMS) technology is to-date, the newest approach to be used in the production of microphones. MEMS has been found to be particularly suited to this purpose, and consumer products markets has created the drive to develop MEMS microphones. At present, commercially produced MEMS microphones are available from many manufacturers, and feature in products such as mobile phones, notebook and tablet computers, audio recorders, and games consoles. The manufacturing process is particularity suited to mass production and the volumes needed to supply the consumer products markets means that unit costs are very attractive. However there have previously been no manufacturers producing a commercially available measurement microphone. Furthermore the frequency response of many commercially available MEMS microphone devices is not adequate for measurement application as their frequency response exceeds the corresponding tolerances requirements for IEC 61672 Class 2 systems. For example, a typical MEMS microphone package encloses the microphone in a cavity, with access to the acoustic field being achieved through a small hole in the package. This arrangement forms a resonant system known as a Helmholz resonator. This resonance causes significant unwanted changes in the frequency response. However for voice applications, such as mobile phone microphones, this resonance can be placed outside the range of voice frequencies, for example at 14 kHz, and produces no significant detriment. Nevertheless, the onset of the resonance begins around 2 kHz, and this onset and the resonance peak are all within the operating bandwidth of a general purpose measurement microphone.

However, in preferred embodiments of the invention, for example by providing a MEMS microphone with an alternative packaging format with integral acoustic filter configured as described herein, or in limited cases by using an unpackaged MEMS microphone with exposed diaphragm, MEMS microphone technology can be utilised in a measurement microphone system. MEMS microphones overcome the economic constraints associated with traditional measurement microphones and have the potential to revolutionise measurement practices. They are readily available as components at very low cost.

The cost of a traditional microphone arises from the piece-wise manufacturing process and need for hand assembly. In contrast MEMS microphones can be manufactured in large numbers (1000s at a time) in one process.

The reduced cost of the microphone system means that the spatial and temporal sampling of many noise assessments can be feasibly increased. Many machinery and environmental noise monitoring applications can benefit from increased spatial sampling. Indeed, significant reduction in the cost of noise measurement is likely to expand the number of applications and business activities that can use noise measurement to their benefit.

Preferably, the acoustic filter includes a resistive element and a closed volume or chamber configured to act as an acoustic compliance; the acoustic filter being configured to behave as a low-pass filter by analogy with an electrical network formed by a series connected resistance and capacitance (electrical R-C network). This arrangement can be particularly advantageous when the microphone is a pressure response microphone, for example an MEMS microphone, as it can compensate for the alteration of the frequency response caused by diffraction when the microphone is used in a free field.

Preferably, the closed volume is provided by a filter housing including a cavity, which cavity is closed by the resistive element.

Preferably, the method includes configuring the volume and the aspect ratio of the closed volume to achieve a desired acoustic compliance, wherein the desired acoustic compliance preferably corresponds to the compensatory response.

Preferably, providing an acoustic filter includes:
providing a plurality of resistive material samples of substantially the same thickness and of various porosities;
selecting from the plurality of resistive material samples the most porous resistive material sample that provides an over-damped response when used to close a cavity of a sample housing to form a closed volume;
selecting a thickness of said most porous resistive material sample that yields a desired acoustic resistance when used to close the cavity of the sample housing, wherein the desired acoustic resistance preferably corresponds to the compensatory response; and
providing the acoustic filter with a or the resistive element corresponding to the thickness and material of said most porous resistive material sample.
Selecting from the plurality of resistive material samples the most porous resistive material sample that provides an over-damped response when used to close a cavity of a sample housing to form a closed volume can include sequentially closing the cavity of the sample housing with each of the plurality of resistive material samples and determining the response.

Preferably, when selecting from the plurality of resistive material samples the most porous resistive material sample that provides an over-damped response when used to close a cavity of a sample housing to form a closed volume, the cavity of that sample housing has a volume and aspect ratio configured to achieve an acoustic compliance corresponding to the compensatory response, and selecting a thickness of said most porous resistive material sample that yields a desired acoustic resistance includes selecting a thickness of said most porous resistive material sample that when used to close the cavity of the sample housing provides the sample housing with a frequency response substantially equal to the compensatory response.

The sample housing can be the filter housing of the acoustic filter, or it can be a separate housing.

Where an acoustic resistance and/or an acoustic compliance are described as corresponding to the compensatory response, a filter with that acoustic resistance and that acoustic compliance can have a frequency response substantially equal to the compensatory response.

According to an aspect of the invention, there is provided an acoustic filter for compensating for a divergence of a frequency response of a microphone system from a desired frequency response of a microphone system, the acoustic filter including a resistive element, and a closed volume configured to act as an acoustic compliance; the acoustic filter being configured to behave as a low-pass filter, by analogy with an electrical network formed by a series connected resistance and capacitance (electrical R-C network).

Preferred embodiments of the invention relate to acoustic filters having responses that can be predicted from the associated lumped acoustic parameters, that can be applied to systems to compensate for undesirable deviations from the required acoustic frequency response of the system.

Preferred embodiments also relate to the use of such filters as replacement housings for commercially available MEMS microphones enabling them to have a frequency response meeting UIEC 61672 Class 1 requirements.

Preferred embodiments also relate to acoustic filters constructed from porous and solid materials where the porous element provides an acoustic impedance that is purely resistance, affording a degree of protection from steady flow in the medium of measurement, for example wind in airborne acoustic measurements.

Preferred embodiments also relate to acoustic filters constructed from porous and solid materials affording a degree of protection from ingress of moisture, particulates and other fluids, for example rain. In such embodiments, the pore size is preferably small enough to prevent water ingress but still allow air flow.

Porosity or void fraction is a measure of the void (i.e. “empty”) spaces in a material, and is a fraction of the volume of voids over the total volume, between 0-1, or as a percentage between 0-100%. In embodiments, porous materials are materials that provide an acoustic impedance that is acoustic resistance, preferably an acoustic impedance that is purely acoustic resistance.

In preferred embodiments, a housing providing the closed volume of the acoustic filter comprises a porous material providing an acoustic resistance, preferably sintered metal material. Sintered metal products are used widely in applications exploiting the ability to produce complex shapes and their inherently porous nature. For example, the flow resistance properties of porous sintered metal is used to produce silencers for pressure release valves in pneumatic systems. The thermal and viscous losses presented by suitable graded material, reduce the velocity of the airflow as it exits the pneumatic system, thereby reducing the acoustic noise generated. Preferred embodiments of this invention exploit such properties of sintered metal components.

Preferred embodiments of the invention use the frequency response of an RC-circuit type filter to modify the unfiltered response of the microphone sub-system.

Filters in preferred embodiments of the invention are configured to adapt the frequency response of a microphone sub-system to make it useful to as high a frequency as possible as a measurement microphone system.

In embodiments of the invention, the microphone system is configured to avoid resonance behaviour.

Preferred embodiments of the invention use magnitude response characteristics to optimise the frequency response.

Preferred embodiments of the invention are configured to quantify a sound signal received at the microphone system thereby to enable the system to be used in a measurement application.

Many prior art microphone systems are concerned with attenuating the sound outside a main bandwidth of interest to prevent it contributing to the received signal. In contrast, in embodiments of the invention, the filter acts to modify a signal received by the microphone system to enable the system to continue to provide useful information, by extending the frequency range where the frequency response of the system maintains a constant value.

In many prior art arrangements, a filter is used to completely exclude some elements of the signal to which the microphone is exposed (only the pass band and stop band regions are generally of interest to these arrangements). In contrast, the response of the filter in the transition region is an important feature being exploited, and the filter ceases to be useful once the frequency range of the stop-band is reached.

In embodiments of the invention, the filter is used quantitatively. In other words, the magnitude of the frequency response of the filter at every frequency in the range of operation has a precise predetermined value.

Many prior art filters are used to address artifacts created within a transducer (either the housing or the microphone). In embodiments of the present invention, the filter is configured to counteract the influence of the microphone or microphone sub-system interacting with an impinging sound wave. In embodiments, in the absence of such interaction (for example at low frequencies) the microphone already has the required response. However because there are increasing interactions at higher frequency due to the wavelength of sound becoming comparable with the diameter of the housing, and causing diffraction, these effects are ‘equalised’ by the filter.

According to an aspect of the invention, there is provided a method of compensating for an undesired frequency response of a microphone sub-system, wherein the microphone sub-system includes a microphone, the method including:
determining an actual frequency response of the sub-system;
determining a compensatory response being substantially equal and opposite to the difference between the actual frequency response of the sub-system and a desired frequency response of the sub-system, wherein the desired frequency response of the sub-system complies with IEC 61672 2001 class 2, and preferably IEC 61672 2001 class 1;
providing an acoustic filter having a response substantially equal to the compensatory response; and
disposing the acoustic filter with respect to the microphone sub-system to modify the frequency response of the sub-system, the sub-system and filter providing a microphone system having a frequency response complying with IEC 61672 2001 class 2, and preferably IEC 61672 2001 class 1.

According to an aspect of the invention, there is provided a microphone system, including:
a microphone sub-system including a microphone; and
an acoustic filter;
wherein the acoustic filter has a frequency response substantially equal and opposite to a difference between a frequency response of the microphone sub-system and a desired frequency response of the system, the desired frequency response of the system complying with IEC 61672 2001 class 2, and preferably IEC 61672 2001 class 1; the acoustic filter being disposed with respect to the microphone sub-system to modify the frequency response of the sub-system to provide the microphone system with a frequency response complying with IEC 61672 2001 class 2, and preferably IEC 61672 2001 class 1.

According to an aspect of the invention, there is provided a microphone system, including:
a microphone sub-system including a microphone;
an acoustic filter;
wherein the frequency response of the microphone is a linear frequency response, preferably a flat frequency response or constant value, in response to a pressure sound field at any frequency in the range 10 Hz to 20 kHz and the acoustic filter is configured to counteract deviations of the frequency response of the microphone from the linear frequency response, flat frequency response or constant value, in response to an incident propagating sound wave, whereby the frequency response of the microphone system is a linear frequency response, preferably a flat frequency response or constant value, in response to an incident propagating sound wave at any frequency in the range 10 Hz to 20 kHz.

The resistive element according to embodiments of the invention includes a porous material. A porous material differs from a housing with an aperture in that the former provides acoustic resistance by design, but has some inherent acoustic mass as a by-product of its construction, whereas an aperture operates primarily as an acoustic mass, but has inherent resistance that can be exploited to control the magnitude of the resonance. This is analogous to electrical resistors and inductors; each has residual elements of inductance and resistance respectively. An acoustic resistive element uses thermal and viscous dissipation mechanisms to extract energy from the acoustic process, usually achieved by having a high ratio of surface area to (enclosed air) volume. An acoustic mass element is characterised by the inertia of the air (related to its mass) moving within it, and usually allows the air to oscillate within the element unconstrained in one dimension. Where there is a constraint, the element acts as a stiffness (for example an open tube and a tube that is closed at one end would be characterised as an acoustic mass and stiffness respectively, whereas a very narrow tube, like a capillary tube, would be classed as an acoustic resistance).

A housing with a hole in it therefore acts in a different way acoustically from a porous material.

To put these ideas into the context of much of the prior art, in designs that intentionally use a Helmholtz resonator, the interplay between the mass and the stiffness determines where the resonance frequency lies, and the resistance determines how sharply the resonance peak is established. In a low pass filter design (as in embodiments of the invention), the interplay between the resistance and stiffness determines where the turning point in the filter lies.

In preferred embodiments, the resistive element and/or the filter housing include(s) sintered metal. Advantages of sintered metal, or similar micro-porous materials (including other porous metallic materials produced by processes other than sintering) include:
It can reduce ingress of water (provided the pore size is sufficiently small)
It can reduce the production of wind noise (in the same was as a wind shield on conventional microphones)
If metallic it provides electrical shielding when used in conjunction with a full metallic housing (though the porous nature is not important in this case).

According to an aspect of the invention, there is provided a method of extending a frequency range at which a microphone sub-system provides a substantially constant frequency response, the method including:
determining an actual frequency response of the microphone sub-system;
determining a compensatory response being substantially equal and opposite to a deviation of the actual frequency response from a substantially constant frequency response;
providing an acoustic filter having a frequency response substantially equal to the compensatory response; and
disposing the filter with respect to the microphone sub-system to modify the frequency response of the sub-system to extend a frequency range at which the microphone sub-system provides a substantially constant frequency response.

Preferably, a substantially constant frequency response is no more than 6 dB above, preferably no more than 4 dB above, and most preferably no more than 2 dB above, a predetermined constant value.

Preferred embodiments of the invention are described below, by way of example only, with reference to the accompanying drawings, in which:

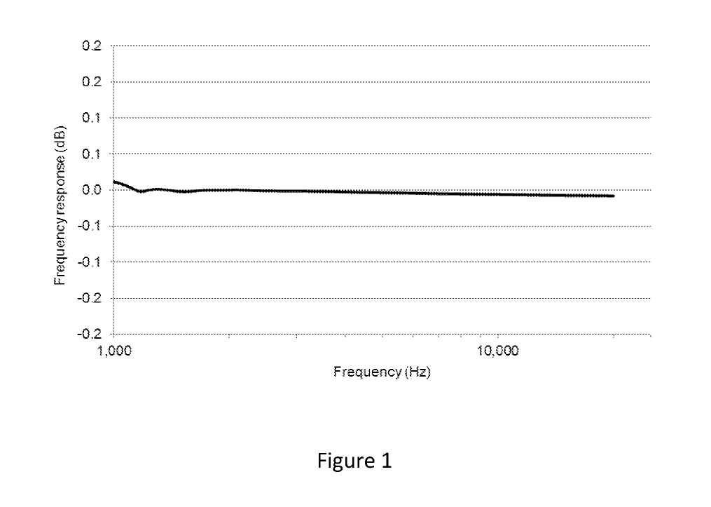

FIG. 1 is a graph showing the frequency response of an MEMS microphone sample when mounted on the ground plane of a hemi-anechoic chamber;

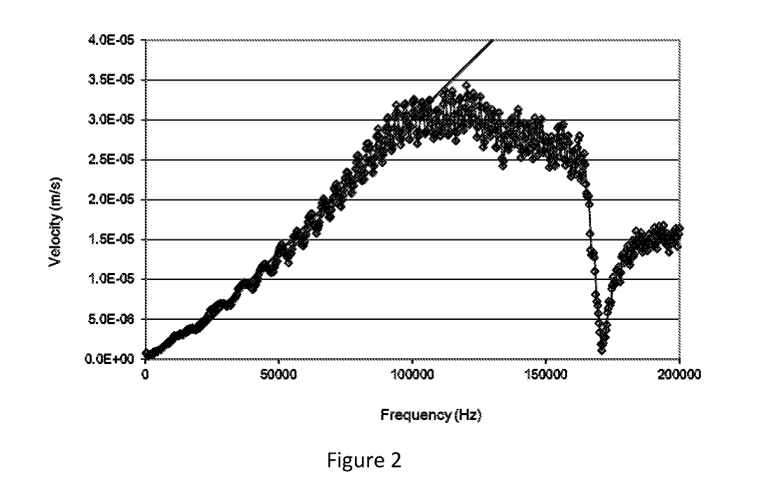

FIG. 2 is a graph showing the diaphragm velocity of an electrically driven MEMS microphone;

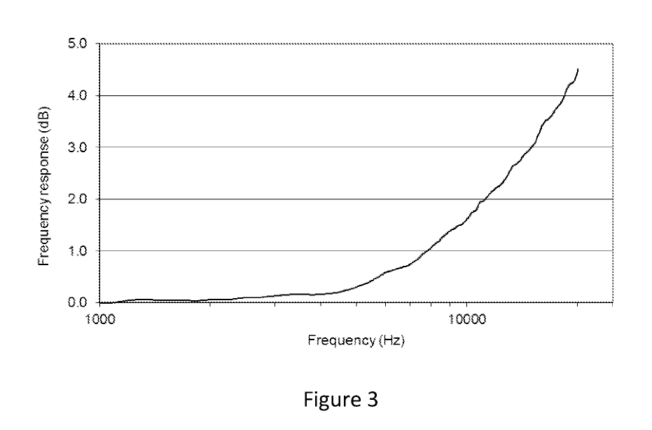

FIG. 3 is a graph showing the free-field frequency response of an MEMS microphone mounted on a 7 mm diameter rod;

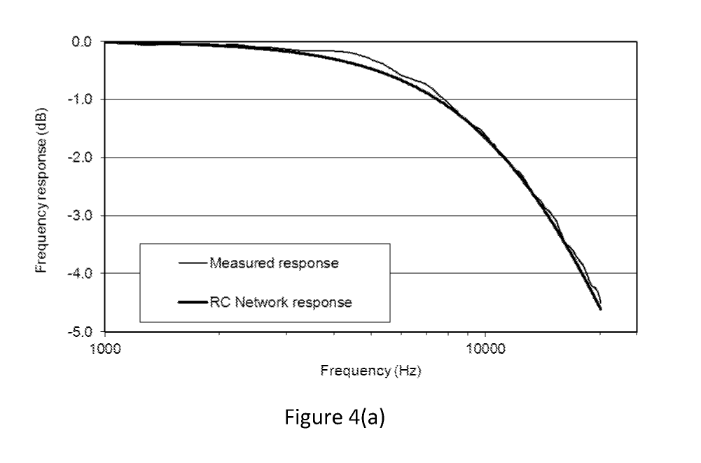

FIG. 4a is a graph showing a frequency response of an R-C network in which R=10MΩ and C=1.1 pF, superimposed on the inverted measured frequency response of FIG. 3;

FIG. 4b is a schematic circuit diagram of an electronic R-C network;

FIG. 4c is a schematic diagram of an acoustic filter according to an embodiment of the invention;

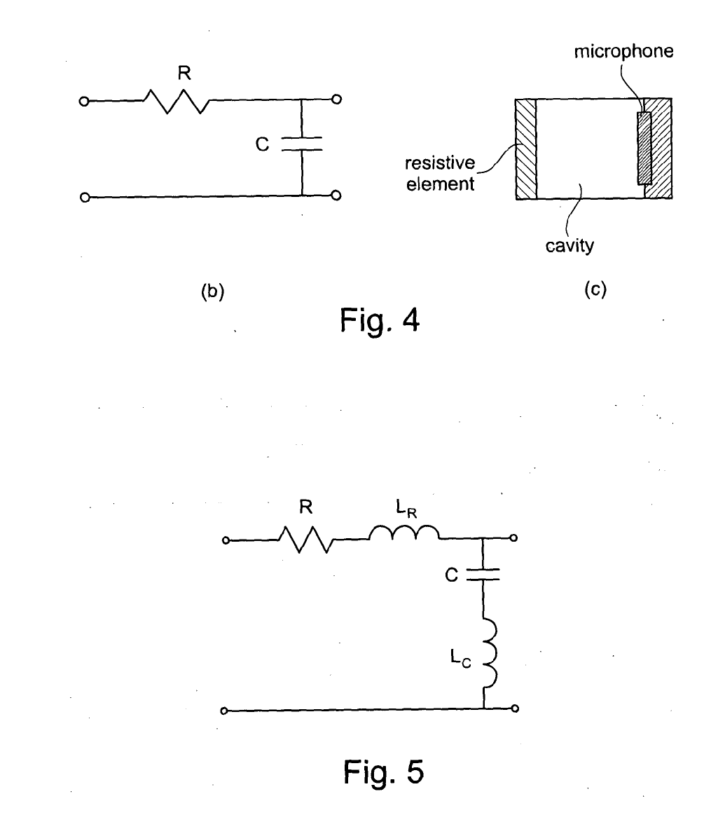

FIG. 5 is a schematic diagram of the electronic equivalent of an acoustic R-C circuit which also accounts for acoustic mass;

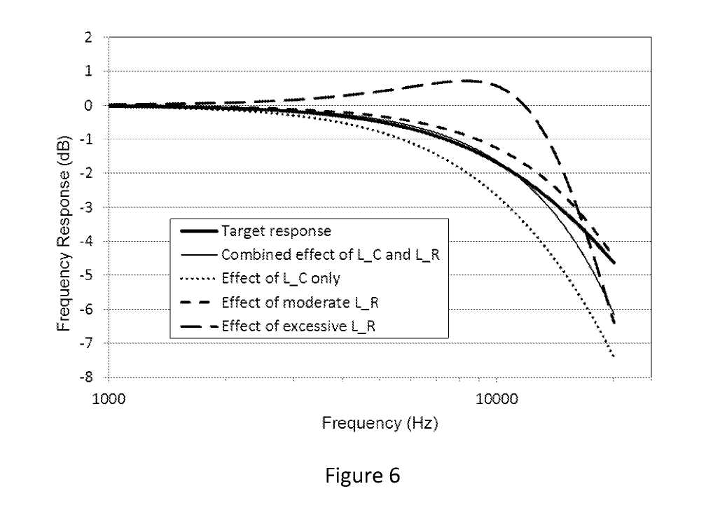

FIG. 6 is a graph showing the influence of an acoustic mass on the response of an R-C network;

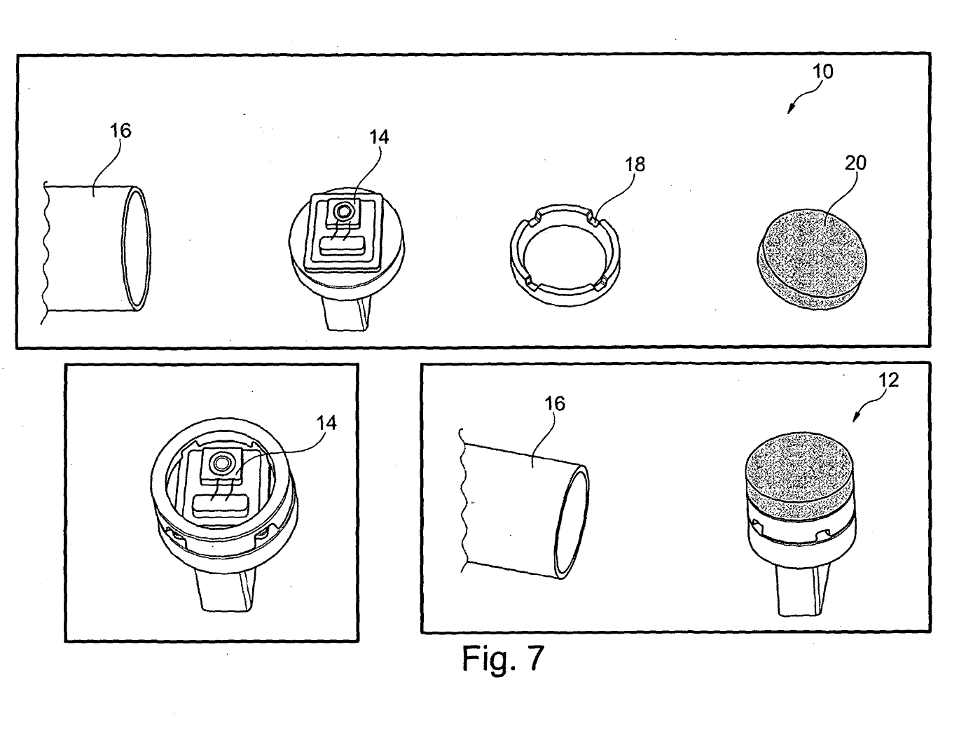

FIG. 7 shows a microphone system according to an embodiment of the invention; and

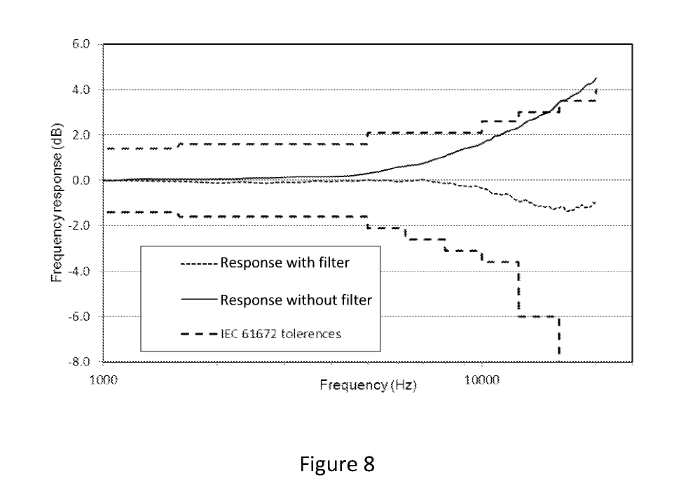

FIG. 8 is a graph showing the response of a microphone with and without a diffraction correcting acoustic filter according to an embodiment of the invention.

As discussed above, generally available MEMS microphone devices cannot be used directly in measurement applications and meet industry standard performance requirements. However, much of the performance limitations have been found to be associated with the way the microphone is packaged, rather than the intrinsic performance of the transducing element itself. Testing of a Wolfson type WM7110 microphone, having removed the cover enclosing the microphone and containing the acoustic port, reveals the microphone to be a pressure type device, having a nominally flat frequency response to a uniformly applied pressure, extending to frequencies well beyond the 20 kHz upper frequency limit of typical noise measurements. Evidence that the microphone is indeed a pressure response device is indicated in FIG. 1 and FIG. 2.

FIG. 1 shows the results of an acoustic test to determine the approximate pressure sensitivity of a Wolfson type WM7110 MEMS microphone. The test was performed by placing the microphone in the plane of the floor of a hemi-anechoic chamber. The microphone was then exposed to plane sound waves from an overhead sound source. The anechoic lining of the chamber ensured that the sound field was largely free of significant reflections and the flush mounting in the ground plane eliminates diffraction. The frequency response of the sound source was equalised using a calibrated reference microphone prior to the measurement of the MEMS microphone. While this method yields the pressure sensitivity in principle, the results show some degrading artifacts. However the resulting frequency response is sufficiently indicative of a pressure response microphone, as opposed to a free-field or diffuse field microphone.

FIG. 2 shows the results of laser vibrometry measurements on the microphone element from a Wolfson type WM7110. For this measurement a d.c. bias voltage of 10V and an a.c. drive voltage of 5V was applied to the microphone. The linear dependence between the velocity and frequency up to 100 kHz indicates that the transducer is behaving as a constant displacement source and in this mode, will also have a constant pressure sensitivity.

A majority of noise measurement applications call for a free-field, or to a lesser degree a diffuse-field microphone to be used. The free-field response of a pressure microphone is typically flat at lower frequencies, and begins to rise with the onset of diffraction, as the acoustic wavelength reduces to become comparable with the size of the microphone. This is exactly the response seen in FIG. 3 which shows the free-field frequency response of an unpackaged Wolfson type WM7110 mounted on the end of a long 7 mm diameter rod. The result in FIG. 3 is further evidence that the microphone is a pressure response type and that the deviation in the frequency response is entirely due to diffraction.

In an embodiment of the invention, an acoustic filter is provided which has a response substantially equal and opposite to the difference between an actual frequency response of a microphone sub-system and the desired frequency response of the microphone system.

In an embodiment, the desired frequency response of the microphone system is a flat frequency response for a normally incident propagating plane wave at any frequency in the range 10 Hz to 20 kHz.

For a microphone sub-system which has the response shown in FIG. 3, the desired response of the filter is the inverted version of the response system shown in FIG. 3.

In an embodiment, the inverted version of the response shown in FIG. 3 can be modelled by the simple R-C-network shown in FIG. 4(b). The graph in FIG. 4(a) shows the frequency response of this network with R=10 MΩ and C=1.1 pF, superimposed on the inverted measured frequency response of FIG. 3 being modelled. Note that any combination of R and C having the same product will produce the same response.

The acoustic interpretation of an R-C-network is a closed volume connected to the sound pressure through a resistive element. Accordingly, FIG. 4(c) shows such a network built on to the microphone the response of which is to be corrected. The microphone of the microphone sub-system is enclosed within a cavity. A housing provides the cavity. The cavity surrounds the microphone but has an opening. The housing also includes the resistive element which closes the opening, thereby providing a closed volume. This provides an acoustic filter according to an embodiment of the invention. The closed volume acts as an acoustic compliance and is analogous to electrical capacitance. Acoustic and electrical resistances are directly equivalent under the same analogy.

The acoustic compliance can be calculated from

C=γP₀/(jωV)

where γ is the ratio of specific heats for air, P₀ is the static pressure, w is the frequency and V the volume of the cavity.

There are a number of options for creating a resistive element, such as meshed screens, fibrous materials, slotted or perforated plates, and porous materials. While some of these mechanisms may have an associated analytical solution for predicting the resistance, there is no common solution, and in some cases no definitive means of determining the resistance. In these cases an experimental determination is necessary.

Some embodiments of the invention utilise porous sintered metal in particular for the resistive element, but other options are not excluded. The reason is twofold. First, the use of a metallic material for the resistive element together with a metallic walled cavity provides the option to electrically screen the microphone element. Second, rigid sintered metal provides a degree of wind screening and protection from rain, eliminating the need for additional accessories to be used.

The embodiment based on the R-C network presented above, makes the assumption that the system is free of inertia, or in network terms, components of acoustic mass. The introduction of acoustic mass in the system leads to the potential for resonances due to the interaction with the acoustic compliance of the cavity.

In practice both the volumetric element and resistance elements have inherent components of mass. Due to their positions within the equivalent circuit, shown in FIG. 5, each has a different influence on the response of the system.

The mass component of the resistive element, L_{R} will tend to increase the response of the system, and ultimately result in a response greater than 0 dB when allowed to become sufficiently greater than the resistance, so that the system becomes under-damped. However the mass component of the compliance element, L_{C} acts in the opposite sense, producing a reduced system response. FIG. 6 illustrates these influences acting independently and in combination.

Preferred embodiments of the invention achieve the correct balance of acoustic mass in the system to obtain the desired response. The mass component of an enclosed volume is fixed by the volume geometry and is given by

L_{C}=lρ/3πa².

where l is the length and a is the cross-sectional area of the cavity, and ρ is the air density.

Therefore the magnitude of L_{C} can be controlled by the aspect ratio of the enclosed volume, while maintaining the actual volume needed to achieve the desired roll-off.

The mass component of the resistive element, for the sintered metal sample is less easy to predict, but the task here is to find the balance between R and L_{R} such that the latter has an insignificant influence, as indicated by an over-damped response. A 2-stage empirical approach has been developed to achieve this. The resistance-to-mass ratio has been found to depend on the porosity grade of the material used to realise the resistance element.

Therefore the first stage of the approach is to conduct a series of experiments to identify the most porous material grade to give an over-damped response. Before experimenting with housings, an initial frequency response of the unhoused microphone is determined to act as a reference response. This microphone is then fitted into a housing cavity of a given cavity size, and a selection of material samples, graded by their porosity and of the same thickness, are used in turn to close the housing. For each configuration, a frequency response of the housed microphone is then determined. The chosen range of material grades should cover both under-damped and over-damped situations. The acoustic influence of each housing assembly is then calculated in terms of the ratio of the housed-to-unhoused microphone responses. This series of results then allows identification of the most porous material grade to give an over-damped response.

The principle of determining the frequency response of the microphone and housing assembly, including the filter under test, is to compare it with another reference microphone system whose response is already known, for example by prior calibration. The comparison is made with both systems exposed to the same sound pressure field, either simultaneously or sequentially. The reference microphone system is calibrated either by a primary calibration method, or by comparison with another reference microphone that is itself ultimately traceable to a primary calibration. For determining the free-field response, the method used follows the principles of IEC 61094-8 which describes free-field calibration of measurement microphones. The method is carried out in a free-field or hemi-anechoic chamber, as required therein. The mounting geometry is carefully controlled to avoid it having any influence on the measurements, as also described in IEC 61094-8. If a hemi-anechoic chamber is used, precautions against reflections from the floor influencing the results are taken. These include flush mounting of the source in the reflecting plane, or the use of time gating in the measurement of the microphone output signals.

After identification of the most porous material grade to give an over-damped response, this material is then selected for use in the second stage of experiments, where the thickness of the material sample is adjusted to achieve the resistance that yields the desired frequency response. In principle, any over-damped response represents one in which the resistance-to-mass ratio is sufficiently large, but heavily over-damped systems may require impractically thin resistive elements.

The porosity and thickness of the porous material, and the geometric details defining the cavity volume, together specify the solution for the diffraction correcting housing.

This method describes a way of finding an optimum filter porosity (or grade) to avoid undue influence from acoustic mass, or from excessive acoustic resistance.

When specifying the free-field frequency response of a microphone it is necessary to consider the overall geometrical configuration including any additional fixtures or equipment to which it is connected, as these strongly influence the response. Consequently, a standardised configuration has been agreed for the specification of the free-field frequency response, where the microphone is mounted on the end of a semi-infinite rod having the same diameter as the microphone.

The geometry of the smallest of the three standardised for measurement microphone has a diameter of 7 mm (IEC type WS3). To maintain compatibility with existing supporting instrumentation and microphone accessories (for example sound calibrators, preamplifiers and mounting devices), a solution for a diffraction correction filter for a MEMS microphone mounted on the end of a semi-infinite 7 mm diameter rod is presented as an example of an embodiment of the invention and shown in FIG. 7.

A microphone system 10 includes a microphone subsystem and a filter 12. The microphone subsystem includes an MEMS microphone 14 and a semi-infinite 7 mm diameter tube 16. The MEMS microphone 14 is a commercially available model, Wolfson Microelectronics type WM7110. The microphone 14 is mounted on a double-sided circular printed circuit board (PCB) with a suitable connector on the opposite side. The lid of the standard microphone packaging is removed.

The filter includes a walled cavity and a resistive element 20. A spacer 18 is used to provide the walls of the cavity and to define the geometry of the cavity for the filter 12.

The spacer 18 is placed onto the printed circuit board to form the cavity with the printed circuit board forming the rear of the cavity and the spacer 18 forming the sides or walls of the cavity. The cavity contains the microphone 14. The cavity volume is approximately 6 mm³. The resistive element 20 is fabricated from sintered bronze having viscous and inertial permeability coefficients of 13×10⁻¹² m² and 18×10⁻⁷ m respectively. The thickness of the resistive element 20 is 0.5 mm.

The resistive element 20 is mounted onto the spacer 18 so as to enclose the microphone 14.

The assembly of the PCB, spacer and filter is then fitted into the tube 16.

Other types of MEMS microphone can be used in place of the Wolfson Microelectronics type WM7110. In addition, fixtures and fittings other than the tube 16 can be used. However, the dimensions used for the filter 12 may need to be adapted in accordance with the required response of the filter 12, as described above.

FIG. 8 shows the response of the microphone 14 with its original manufacturer's packaging removed, mounted on the 7 mm diameter rod 16, both with and without the diffraction correcting filter 12. The IEC 61672 frequency response tolerance limits for a Class 1 system are also shown. Bearing in mind that the microphone has been shown to be a pressure response type, the response without the filter in place clearly shows the influence of diffraction. The response with the filter in place clearly complies with the IEC 61672 Class 1 tolerances.

Uses of acoustic filters to correct for undesirable deviations from the required acoustic frequency response of the system are not limited to the solution described above for MEMS microphones. The same approach can be used for example to alter the response of a pressure or diffuse field microphone to have a flat free-field response, or of a pressure microphone to have a flat diffuse-field response. Alternatively, the approach can be used to accentuate or attenuate a particular feature of a sound by providing the system with a respective rise and then a fall, or a fall and then a rise, in the response around a particular frequency. These and other uses can be realised by appropriate design of the acoustic filter in accordance with the teachings herein.

For example, the acoustic mass elements described above can be configured to yield accentuated bands within the frequency response, as evident from FIG. 6 in which the top response, “Effect of excessive L_{R}” shows a region of accentuated frequencies in which the frequency response is positive. Appropriate configuration of the relative magnitude of the acoustic mass and acoustic compliance of the filter enable the centre frequency of such a region to be adjusted, and the acoustic resistance can be used to adjust the bandwidth. Volume inclusions within the main closed cavity can similarly be used to create bands of attenuation.

Acoustic filters can also be used to correct for the influences on mounting configurations used in-situ. For example, in embodiments of the invention, filters can be produced to compensate for the effects of posts, stands, and other diffracting objects on the frequency response of the system.

All optional and preferred features and modifications of the described embodiments and dependent claims are usable in all aspects of the invention taught herein. Furthermore, the individual features of the dependent claims, as well as all optional and preferred features and modifications of the described embodiments are combinable and interchangeable with one another.

The disclosures in UK patent application number 1204305.5, from which this application claims priority, and in the abstract accompanying this application are incorporated herein by reference.

The following clauses recite the features of advantageous embodiments of the invention.

1. A method of compensating for an undesired frequency response of a microphone system, wherein the microphone system includes a microphone, the method including: the steps of
determining a desired frequency response of the system;
determining an actual frequency response of the system;
determining a compensatory response being substantially equal and opposite to the difference between the actual frequency response of the system and the desired frequency response of the system; and
providing an acoustic filter having a response substantially equal to the compensatory response.
2. A method according to clause 1 wherein the desired frequency response of the system corresponds to a free-field microphone.
3. A method according to clause 1 or 2, wherein the actual frequency response of the system corresponds to a pressure microphone.
4. A method according to any preceding clause, wherein providing an acoustic filter includes enclosing the microphone within the acoustic filter.
5. A method according to clause 4, wherein the acoustic filter includes a resistive element, and a closed volume configured to act as an acoustic compliance; the acoustic filter being configured to behave as a low-pass filter.
6. A method according to clause 1, wherein providing an acoustic filter includes enclosing the microphone within the acoustic filter; wherein the acoustic filter includes a resistive element, and a closed volume configured to act as an acoustic compliance; the acoustic filter being configured to accentuate or attenuate a predetermined frequency range.
7. A method according to clause 5 or 6, wherein the filter includes a metallic walled cavity providing the closed volume, whereby to electrically screen the microphone.
8. A method according to any of clauses 5 to 7, wherein the resistive element includes an element selected from the group including: meshed screens, fibrous materials, slotted or perforated plates, and porous materials; wherein the resistive element preferably includes a porous sintered material.
9. A method according to any of clauses 5 to 9, wherein providing an acoustic filter includes constructing the acoustic filter.
10. A method according to clause 9, wherein constructing the acoustic filter includes configuring the volume and the aspect ratio of the closed volume to achieve the desired acoustic compliance.
11. A method according to any of clauses 5 to 10, wherein providing an acoustic filter includes:
providing a plurality of resistive material samples of substantially the same thickness and of various porosities;
selecting from the plurality of resistive material samples the most porous resistive material sample that provides an over-damped response; and
selecting a thickness of said most porous resistive material sample to achieve the resistance that yields the desired response;
wherein the resistive element corresponds to the thickness and material of said most porous resistive material sample.
   12. A method according to any preceding clause, wherein the microphone is an MEMS microphone.
   13. A microphone system, including:
a microphone sub-system including a microphone; and
an acoustic filter;
wherein the acoustic filter has a frequency response substantially equal and opposite to a difference between a frequency response of the microphone sub-system and a desired frequency response of the system.
   14. A system according to clause 13, wherein the desired frequency response of the system corresponds to a free-field microphone.
   15. A system according to clause 13 or 14, wherein the frequency response of the microphone sub-system corresponds to a pressure microphone.
   16. A system according to any of clauses 13 to 15, wherein the microphone is enclosed within the acoustic filter.
   17. A system according to clause 15, wherein the acoustic filter includes a resistive element, and a closed volume configured to act as an acoustic compliance; the acoustic filter being configured to behave as a low-pass filter
   18. A system according to clause 13, wherein the microphone is enclosed within the acoustic filter; wherein the acoustic filter includes a resistive element, and a closed volume configured to act as an acoustic compliance; the acoustic filter being configured to accentuate or attenuate a predetermined frequency range
   19. A system according to clause 17 or 18 wherein the filter includes a metallic walled cavity providing the closed volume, whereby to electrically screen the microphone element.
   20. A system according to any of clauses 17 to 19 wherein the resistive element includes an element selected from the group including: meshed screens, fibrous materials, slotted or perforated plates, and porous materials; wherein the resistive element preferably includes a porous sintered material.
   21. A system according to any of clauses 13 to 20, wherein the microphone is an MEMS microphone.
   22. An acoustic filter for compensating for a divergence of a frequency response of a microphone system from a desired frequency response of a microphone system, the acoustic filter including a resistive element, and a closed volume configured to act as an acoustic compliance; the acoustic filter being configured to behave as a low-pass filter.
   23. A sound level meter including a microphone system according to any of clauses 13 to 21.

1. A method of compensating for an undesired frequency response of a microphone sub-system for a measurement microphone system, wherein the microphone sub-system includes a microphone, the method including:
determining a desired frequency response of the sub-system;
determining an actual frequency response of the sub-system;
determining a compensatory response being substantially equal and opposite to the difference between the actual frequency response of the sub-system and the desired frequency response of the sub-system; and
providing a low-pass acoustic filter including a resistive element, and a closed volume configured to act as an acoustic compliance, the acoustic filter being configured to have a frequency response substantially equal to the compensatory response.

2-3. (canceled)

4. A method according to claim 1, wherein providing an acoustic filter includes enclosing the microphone within the acoustic filter; the acoustic filter being configured to accentuate or attenuate a predetermined frequency range.

5-17. (canceled)

18. A method according to claim 1, wherein providing an acoustic filter includes constructing the acoustic filter, and wherein constructing the acoustic filter preferably includes configuring the volume and the aspect ratio of a or the closed volume to achieve a desired acoustic compliance.

19. (canceled)

20. A method according to claim 1, wherein providing an acoustic filter includes:
providing a plurality of resistive material samples of substantially the same thickness and of various porosities;
selecting from the plurality of resistive material samples the most porous resistive material sample that provides an over-damped response when used to close a cavity of a housing to form a or the closed volume;
selecting a thickness of said most porous resistive material sample that yields a desired acoustic resistance; and
providing the acoustic filter with a or the resistive element corresponding to the thickness and material of said most porous resistive material sample.

21. (canceled)

22. A measurement microphone system, including:
a microphone sub-system including a microphone; and
an acoustic filter configured to behave as a low-pass filter;
wherein the acoustic filter includes a resistive element, and a closed volume configured to act as an acoustic compliance, the acoustic filter being configured to have a frequency response substantially equal and opposite to a difference between a frequency response of the microphone sub-system and a desired frequency response of the system.

23. A system according to claim 22, wherein the resistive element has an acoustic impedance which is substantially purely resistive, and/or wherein the filter is configured as an RC-circuit type filter, and/or wherein the acoustic filter is disposed with respect to the microphone sub-system to modify the frequency response of the sub-system to provide the microphone system with a frequency response substantially corresponding to the desired frequency response, and/or wherein the frequency response of the microphone system complies with IEC 61672 2001 class 2, and preferably IEC 61672 2001 class 1.

24. (canceled)

25. A system according to claim 22, wherein the microphone is enclosed within the acoustic filter; the acoustic filter being configured to accentuate or attenuate a predetermined frequency range.

26. A system according to claim 22, wherein the desired frequency response of the system is a linear frequency response for the frequency range 10 Hz to 20 kHz, and wherein the desired frequency response of the system is a preferably flat frequency response, and preferably a constant value, for the frequency range 10 Hz to 20 kHz.

27-29. (canceled)

30. A system according to claim 22, wherein the frequency response of the microphone system is no more than 6 dB above, preferably no more than 4 dB above, and most preferably no more than 2 dB above, the desired frequency response at all points of the frequency range 10 Hz to 20 kHz.

31. (canceled)

32. A system according to claim 22, wherein the actual and desired frequency responses are in response to a normally incident propagating plane wave, and/or wherein the desired frequency response corresponds to a free-field microphone, and/or wherein the actual frequency response of the microphone sub-system corresponds to a pressure microphone.

33-34. (canceled)

35. A system according to claim 22, wherein the microphone is enclosed within the acoustic filter, and/or wherein the filter includes a metallic walled cavity providing a or the closed volume, whereby to electrically screen the microphone element, and/or wherein a or the resistive element includes an element selected from the group consisting of: meshed screens, fibrous materials, slotted or perforated plates, and porous materials; wherein the resistive element preferably includes a porous sintered material.

36-38. (canceled)

39. A system according to claim 22, wherein the microphone is an MEMS microphone.

40. A sound level meter including a microphone system according to claim 22.

41. A method of designing a filter for compensating for an undesired frequency response of a microphone sub-system of a measurement microphone system, wherein the microphone sub-system includes a microphone, the method including:
determining a desired frequency response of the sub-system;
determining an actual frequency response of the sub-system;
determining a compensatory response being substantially equal and opposite to the difference between the actual frequency response of the sub-system and the desired frequency response of the sub-system; and
determining a configuration of a closed volume to act as an acoustic compliance, and a configuration of a resistive element, wherein the determined configurations of a resistive element and acoustic compliance are usable in a low-pass acoustic filter to provide a frequency response substantially equal to the compensatory response.

42. A method according to claim 41, including:
providing a sample housing including a cavity which can be closed to provide a closed volume;
providing a plurality of resistive material samples of substantially the same thickness and of various porosities;
selecting from the plurality of resistive material samples the most porous resistive material sample that provides an over-damped response when used to close the sample housing; and
selecting a thickness of said most porous resistive material sample that yields a desired acoustic resistance;
wherein the selected resistive material sample is usable in a filter providing a frequency response substantially equal to the compensatory response, wherein providing a sample housing preferably includes configuring the volume and the aspect ratio of the closed volume of the sample housing to achieve a desired acoustic compliance.

43. (canceled)

44. A method of making a filter, including:
designing a filter using the method of claim 41; and
making a filter using a housing corresponding to the sample housing, being closed with a resistive element corresponding to the thickness and material of said most porous resistive material sample that yields a desired acoustic resistance.

45. A method according to claim 1, wherein the resistive element has an acoustic impedance which is substantially purely resistive, and/or wherein the filter is configured as an RC-circuit type filter, and/or wherein the acoustic filter is disposed with respect to the microphone sub-system to modify the frequency response of the sub-system to provide the microphone system with a frequency response substantially corresponding to the desired frequency response, and/or wherein the frequency response of the microphone system complies with IEC 61672 2001 class 2, and preferably IEC 61672 2001 class 1.

46. A method according to claim 1, wherein the desired frequency response of the system is a linear frequency response for the frequency range 10 Hz to 20 kHz, and wherein the desired frequency response of the system is a preferably flat frequency response, and preferably a constant value, for the frequency range 10 Hz to 20 kHz.

47. A method according to claim 1, wherein the frequency response of the microphone system is no more than 6 dB above, preferably no more than 4 dB above, and most preferably no more than 2 dB above, the desired frequency response at all points of the frequency range 10 Hz to 20 kHz.

48. A method according to claim 1, wherein the actual and desired frequency responses are in response to a normally incident propagating plane wave, and/or wherein the desired frequency response corresponds to a free-field microphone, and/or wherein the actual frequency response of the microphone sub-system corresponds to a pressure microphone.

49. A method according to claim 1, wherein the microphone is enclosed within the acoustic filter, and/or wherein the filter includes a metallic walled cavity providing a or the closed volume, whereby to electrically screen the microphone element, and/or wherein a or the resistive element includes an element selected from the group consisting of: meshed screens, fibrous materials, slotted or perforated plates, and porous materials; wherein the resistive element preferably includes a porous sintered material.

50. A method according to claim 1, wherein the microphone is an MEMS microphone.
